(19) United States
(12) Patent Application Publication
(10) Pub. No.: US 2012/0168082 A1
(43) Pub. Date: Jul. 5, 2012

(54) PLASMA GENERATING APPARATUS

(75) Inventors: Shinichi Izuo, Tokyo (JP); Yukihisa Yoshida, Tokyo (JP); Takaaki Murakami, Tokyo (JP)

(73) Assignee: Mitsubishi Electric Corporation, Tokyo (JP)

(21) Appl. No.: 13/394,015

(22) PCT Filed: Jul. 15, 2010
(86) PCT No.: PCT/JP10/61979

§ 371 Date: Mar. 2, 2012

(30) Foreign Application Priority Data
Sep. 15, 2009 (JP) 2009-212965

(51) Int. Cl. H01L 21/3065; H01J 61/28; C23C 16/50

(52) U.S. Cl. 156/345.44; 118/723 E; 313/231.31

(57) ABSTRACT

A plasma generating apparatus irradiates plasma on a treatment object. The plasma is generated under gas pressure equal to or higher than 100 pascals and equal to or lower than atmospheric pressure in an inter-electrode gap between a first electrode to which a power supply is connected and a second electrode arranged to be opposed to the first electrode and grounded. The first electrode has a structure in which the first electrode is retained on a grounded conductive retaining member via a solid dielectric provided on a surface not opposed to the second electrode, and a conductive film is continuously provided on a surface in a predetermined range in contact with the conductive retaining member and a surface in a predetermined range not in contact with the conductive retaining member on a surface of the solid dielectric.

### FIELD

The present invention relates to a plasma generating apparatus that changes a reactant gas to a plasma state, and, more particularly to a plasma generating apparatus that generates cold plasma.

### BACKGROUND

In a manufacturing process for a semiconductor device, an imaging device, or a line sensor for image input, a plasma process for performing treatment such as thin film formation, etching, sputtering, and surface modification is an essential technology. In this plasma process, cold plasma in which gas temperature is low and only electron temperature is high is widely used.

In a plasma generating apparatus in the past that generates the cold plasma, a power-supply electrode to which pulse power and high-frequency power are applied is arranged in a grounded vacuum chamber while being insulated from the vacuum chamber. The other electrode opposed to the power-supply electrode is arranged to be electrically connected to the vacuum chamber. An arrangement space of the electrodes is filled with a reactant gas adjusted to gas pressure of several pascals to 100 pascals. In this plasma generating apparatus, the reactant gas between the electrodes is ionized by an electric discharge due to a pulse-like electric field and a high-frequency electric field generated between the electrodes and a plasma state (cold plasma) in which electrons having negative charges, ions having positive charges, and electrically neutral radicals are mixed while violently moving is generated between the electrodes.

In the plasma generating apparatus having such a configuration, an electric field is also generated between the vacuum chamber and the power-supply electrode. Therefore, in some case, a plasma discharge also occurs between the vacuum chamber and the power-supply electrode. The electric discharge that occurs between the vacuum chamber and the power-supply electrode is an unnecessary discharge and is a hindrance in improving plasma generation efficiency. Therefore, in the past, various structure examples for suppressing the unnecessary discharge that occurs between the vacuum chamber and the power-supply electrode have been proposed (e.g., Patent Literatures 1 and 2).

### CITATION LIST

### Patent Literature

Patent Literature 1: Japanese Patent No. 3280052 (FIG. 1)
Patent Literature 2: Japanese Patent No. 3253122 (FIGS. 1 and 2)

### SUMMARY

### Technical Problem

The unnecessary discharge suppressing structure examples in the past explained above are applied when gas pressure in the vacuum chamber is adjusted to be within a range of several pascals to 100 pascals. However, the present invention intends to obtain a plasma generating apparatus in which the unnecessary discharge does not occur even in a pressure range higher than the pressure range (several pascals to 100 pascals) used in the past, specifically, a pressure range equal to or higher than 100 pascals and equal to or lower than the atmospheric pressure.

In this case, according to the Paschen's law, a discharge start voltage of plasma is represented by a function of a product of gas pressure and an inter-electrode gap. Therefore, when the gas pressure increases, the inter-electrode gap likely to cause an electric discharge decreases. In a range in which the gas pressure is equal to or higher than 100 pascals and equal to or lower than the atmospheric pressure, a gap most likely to cause an electric discharge is in a range of 0.1 millimeter to 1 millimeter.

Then, in the unnecessary discharge suppressing structure examples proposed in the past, a place where the gap most likely to cause an electric discharge obtained from the Paschen's law is present or formed. Therefore, there is a problem in that, when an electric discharge for generating plasma is caused under a condition of high gas pressure equal to or higher than 100 pascals and equal to or lower than the atmospheric pressure, the unnecessary discharge also occurs.

Specifically, in the unnecessary discharge suppressing structure example shown in FIG. 1 of Patent Literature 1, when explained using reference numerals shown in FIG. 1, to secure insulation of the power-supply electrode (2), it is necessary to secure a gap between the earth shield (5) and the power-supply electrode (2). Therefore, the unnecessary discharge occurs in the gap.

In the unnecessary discharge suppressing structure example shown in FIG. 2 of Patent Literature 2, when explained using reference numerals shown in FIG. 2, because the insulator (11) is arranged around the power-supply electrode (3), short-circuit of the power-supply electrode (3) and the earth shield (4) can be prevented. However, because the insulator (11) is charged, an electric discharge occurs in the gap between the earth shield (4) and the insulator (11).

In the unnecessary discharge suppressing structure example shown in FIG. 1 of Patent Literature 2, when explained using reference numerals shown in FIG. 1, insulation of the vacuum chamber (1) and the power-supply electrode (3) is kept by the insulator (11). However, in the machine assembly structure that makes the power-supply electrode (3) detachably attachable to the vacuum chamber (1), a gap is inevitably formed between the insulator (11) and the vacuum chamber (1) or between the insulator (11) and the power-supply electrode (3) because of a dimensional tolerance of assembly. The unnecessary discharge occurs in the gap.

The present invention has been devised in view of the above and it is an object of the present invention to obtain a plasma generating apparatus that can prevent, even if plasma is generated at gas pressure equal to or higher than 100 pascals and equal to or lower than the atmospheric pressure, an electric discharge in a place where the electric discharge is unnecessary and can realize improvement of plasma generation efficiency.

### Solution to Problem

In order to attain the above object, in a plasma generating apparatus of the present invention that irradiates plasma on a treatment object, the plasma is generated under gas pressure equal to or higher than 100 pascals and equal to or lower than atmospheric pressure in an inter-electrode gap between a first electrode to which a power supply is connected and a second electrode arranged to be opposed to the first electrode and grounded. Additionally, the first electrode has a structure in which the first electrode is retained on a grounded conductive retaining member via a solid dielectric provided on a surface not opposed to the second electrode, and a conductive film is continuously provided on a surface in a predetermined range in contact with the conductive retaining member and a surface in a predetermined range not in contact with the conductive retaining member on a surface of the solid dielectric.

### Advantageous Effects of Invention

According to the present invention, when the first electrode is supported by the grounded conductive retaining member, because the conductive film on the side in contact with the conductive retaining member is grounded through the conductive retaining member, an electric discharge does not occur in a gap between the conductive film on the side not in contact with the conductive retaining member and the conductive retaining member. Therefore, because an electric discharge in a place where the electric discharge is unnecessary can be prevented even if plasma is generated at high gas pressure equal to or higher than 100 pascals and equal to or lower than the atmospheric pressure, there is an effect that improvement of plasma generation efficiency can be realized.

### BRIEF DESCRIPTION OF DRAWINGS

FIG. 1 is a sectional schematic view of the configuration of a plasma generating apparatus according to a first embodiment of the present invention.

FIG. 2 is a sectional schematic view of the configuration of a plasma generating apparatus according to a second embodiment of the present invention.

### DESCRIPTION OF EMBODIMENTS

Embodiments of a plasma generating apparatus according to the present invention are explained in detail below based on the drawings. The present invention is not limited by the embodiments.

### First Embodiment

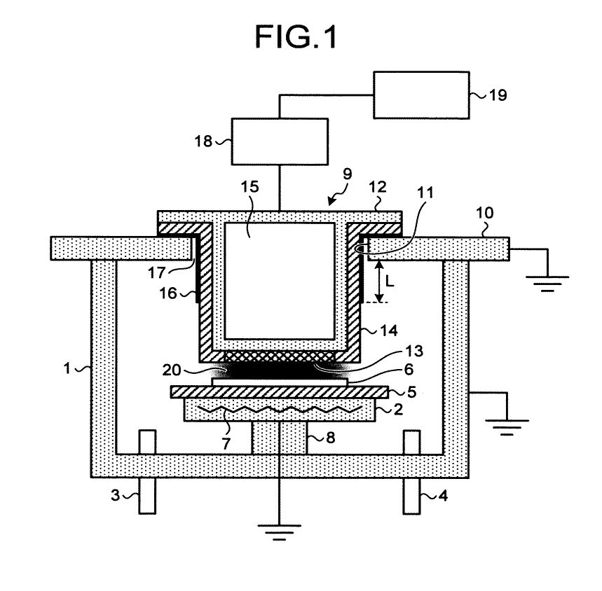

FIG. 1 is a sectional schematic view of the configuration of a plasma generating apparatus according to a first embodiment of the present invention. In FIG. 1, a reaction vessel 1 serving as a vacuum chamber is obtained by forming a conductive member in a bottomed cylindrical shape and is electrically grounded. An electrically-grounded flat ground electrode stage 2 is arranged on the bottom of the reaction vessel 1. A gas lead-in port 3 and a gas exhaust port 4 are provided in the bottom of the reaction vessel 1. A substrate 6 set as a treatment object is arranged on the upper surface of the ground electrode stage 2 via a solid dielectric 5. The ground electrode stage 2 incorporates a heater 7 and can heat the substrate 6 via the solid dielectric 5. In FIG. 1, the ground electrode stage 2 is supported, in parallel to the bottom surface of the reaction vessel 1, at an end of a column 8 having predetermined height fixed substantially in the center of the bottom of the reaction vessel 1 (in an example shown in the figure, in the position of the center of a cylinder). This ground electrode stage 2 configures a second electrode in claim 1.

A flat retaining plate 10 that supports an electrode set 9 is fixed to an opening end face of the reaction vessel 1. The external appearance of the electrode set 9 has a shape formed by an inserting section having a columnar shape of predetermined length and a flange section provided to project in the radial direction of the inserting section on a draw-out side of the inserting section. The retaining plate 10 is made of a conductive member and electrically grounded. In the retaining plate 10, a circular hole 11 slightly larger than the outer diameter of the inserting section of the electrode set 9 is provided. In the example shown in the figure, the center of this circular hole 11 coincides with the center of the cylinder. The retaining plate 10 is used as a cover that closes the opening end of the reaction vessel 1.

The electrode set 9 includes a power-supply electrode 12, an electrode plate 13, and a solid dielectric 14. The power-supply electrode 12 is a columnar structure having the inserting section and the flange section explained above. The electrode plate 13 is bonded to the end face of the inserting section. The solid dielectric 14 is continuously bonded to the outer circumference of the inserting section, excluding an arrangement area of this electrode plate 13, and an inserting side of the flange section. A hollow 15 is provided on the inside of the power-supply electrode 12. A coolant such as water is filled in the hollow 15 to make it possible to cool the electrode plate 13. The power-supply electrode 12 and the electrode plate 13 configure a first electrode in claim 1.

The length of the electrode set 9 is set to length with which the electrode set 9 is supported by the retaining plate 10 in a state in which an inserting end of the electrode set 9 is fit in the circular hole 11 of the retaining plate 10 and the flange section provided on the draw-out end side collides with the retaining plate 10 around the circular hole 11, whereby the electrode plate 13 on the end face of the inserting section is opposed to the substrate 6 while maintaining an appropriate space.

In the electrode set 9, the flange section provided on the draw-out end side is hermetically fixed to the retaining plate 10 by not-shown screws. Consequently, the reaction vessel 1 serves as a vacuum chamber that can be decompressed by releasing so-called air on the inside of the reaction vessel 1. In the example shown in the figure, flange sections are provided in both of the power-supply electrode 12 and the solid dielectric 14. However, in principle, it is unnecessary to provide the flange section in the power-supply electrode 12. In the configuration shown in the figure, it is possible to reduce possibility of damage to the solid dielectric 14 by screwing the power-supply electrode 12 to the retaining plate 10 integrally with the solid dielectric 14. In other words, it is desirable to provide the flange section in the power-supply electrode 12 as well.

In the electrode set 9, a conductive film 16 is formed by a method explained later on a surface in a predetermined range of the solid dielectric 14 near the retaining plate 10 supported by the retaining plate 10. When the electrode set 9 is fit in the circular hole 11 of the retaining plate 10 and the flange section is supported by the retaining plate 10, the conductive film 16 formed on the flange section is compression-bonded to the retaining plate 10 and electrically connected to the ground through the retaining plate 10. The inner circumferential diameter of the circular hole 11 of the retaining plate 10 is formed with a margin enough for forming a gap 17 between the circular hole 11 and the conductive film 16 formed on the inserting section. Therefore, it is possible to set the electrode set 9 in the reaction vessel 1 without causing the conductive film 16 and the circular hole 11 of the retaining plate 10 to interfere with each other. In this way, the attachment and detachment of the electrode set 9 and the reaction vessel 1 can be easily performed only tightening and releasing the screws.

A power supply 19 is connected to the power-supply electrode 12 of the electrode set 9 via a matching box (an impedance matching box) 18. The power supply 19 is, for example, a high-frequency power supply of 13.56 megahertz, a high-frequency power supply of about several hundred megahertz higher than 13.56 megahertz, or a pulse power supply of several kilohertz.

In the configuration explained above, a supply amount of a reactant gas led in from the gas lead-in port 3 and an exhaust amount of the reactant gas discharged from the gas exhaust port 4 are adjusted such that the pressure of the reactant gas in the reaction vessel 1 is set to a fixed value within a range equal to or higher than 100 pascals and equal to or lower than the atmospheric pressure in a state in which the so-called air in the reaction vessel 1 is discharged from the gas exhaust port 4 to set the reaction vessel 1 to a predetermined degree of vacuum. A coolant is led into the hollow 15 to cool the electrode plate 13 to certain temperature and the heater 7 is caused to generate heat to heat the substrate 6 to certain temperature. In this state, when predetermined high-frequency power or pulse power is applied from the power supply 19 to the power-supply electrode 12 through the matching box 18, an electric discharge is started between the electrode plate 13, which is a part of the power-supply electrode 12, and the ground electrode stage 2 and plasma 20 is generated. The substrate 6 is exposed to this plasma 20, whereby predetermined plasma treatment is applied to the substrate 6.

For example, when a hydrogen gas is used as the reactant gas, a silicon plate is used as the electrode plate 13, the electrode plate 13 is cooled by a coolant of about 15° C., the substrate 6 is heated to about 300° C., gas pressure in the reaction vessel 1 is adjusted to about 0.9 atmospheres, and the plasma 20 is generated, a silicon film is formed on the substrate 6. In the example explained above, a functional thin film is formed on the substrate 6. However, surface modification treatment for the substrate 6 can be performed by the same method.

In this case, even in a state in which the substrate 6 was exposed to the plasma 20 generated between the electrode plate 13 and the ground electrode stage 2, a plasma discharge did not occur in the area of the gap 17. This is considered to be because field intensity between the solid dielectric 14 and the conductive film 16, which is at the ground potential, in the area of the gap 17 does not reach field intensity necessary for an electric discharge. However, a large electric field is applied to the solid dielectric 14 interposed between the conductive film 16 and the power-supply electrode 12. Therefore, as the solid dielectric 14, it is necessary to select a solid dielectric having thickness and made of a material that can withstand the large field intensity. For example, when alumina is used as the solid dielectric 14, the thickness of the solid dielectric 14 is desirably equal to or larger than 3 millimeters from the viewpoint of withstand voltage properties and mechanical strength.

A method of setting an area where the conductive film 16 should be formed is explained. It was examined whether a conductive film needed to be also formed in an area other than the area of the gap 17 where the inner circumferential surface in predetermined width of the circular hole 11 of the retaining plate 10 and the solid dielectric 14 are opposed to each other, i.e., a belt-like area of width L extending from the lower end of the circular hole 11 of the retaining plate 10 to the distal end of the inserting section of the electrode set 9.

If the gas pressure in the reaction vessel 1 is the atmospheric pressure, the dimension of the width L only has to be 0 millimeter. In other words, it was sufficient to form the conductive film 16 only in the area of the gap 17. On the other hand, when the gas pressure in the reaction vessel 1 was set smaller than the atmospheric pressure and set to gas pressure of 100 pascals, an electric discharge between the solid dielectric 14 and the reaction vessel 1 was able to be prevented by setting the dimension of the width L to be equal to or larger than 5 millimeters. Therefore, it was confirmed that the dimension of the width L extending beyond the gap 17 of the conductive film 16 might be 0 millimeter at the atmospheric pressure but, to prevent plasma generation between the reaction vessel 1 and the solid dielectric 14 in a wide range of gas pressure from 100 pascals to the atmospheric pressure, the dimension was desirably equal to or larger than 5 millimeters. The dimension of the width L extending beyond the gap 17 of the conductive film 16 is set as a space distance between the solid dielectric 14 and the grounded reaction vessel 1. Therefore, when a retaining structure changes, the conductive film 16 only has to be formed on the surface of the solid dielectric 14, a space between which and the grounded retaining plate 10 is equal to or smaller than 5 millimeters.

A method of forming the conductive film 16 is explained. First, an area of the solid dielectric 14 where the conductive film 16 is not formed is masked by sticking a film to the area. The masked solid dielectric 14 is immersed in nickel plating liquid. A nickel film having thickness of about several microns is formed by electroless plating. Gold plating coating is applied to the surface of the nickel film as coating for preventing oxidation of the surface of the nickel film. The film used for the masking is peeled. Consequently, the solid dielectric 14 on which a nickel/gold film serving as the conductive film 16 is formed only in a desired place is obtained. The material of the conductive film 16 is not limited to the nickel/gold film and only has to be a material that is film-like and can be formed by coating and the surface of which is not oxidized. As another member, for example, a paste containing manganese and molybdenum is applied to the surface of a dielectric and a nickel film is formed on the paste film by plating. A cobalt alloy is welded to this nicked film. The cobalt alloy can be welded to the retaining plate 10 serving as a conductive retaining member.

The thickness of the conductive film 16 is desirably equal to or larger than 0.1 micrometer and equal to or smaller than 100 micrometers. This is because, at the thickness equal to or smaller than 0.1 micrometer, when the electrode set 9 is fit in the circular hole 11 of the retaining plate 10, if the thin conductive film 16 and the inner circumference of the circular hole 11 come into contact with each other even a little, the conductive film 16 is scratched, the surface of the solid dielectric 14 is exposed to the gap 17 side, and prevention of an unnecessary discharge cannot be performed. At the thickness equal to or larger than 100 micrometers, film distortion due to internal stress of the conductive film 16 increases, the conductive film 16 peels from the solid dielectric 14, a gap is formed between the conductive film 16 and the solid dielectric 14, and a plasma discharge occurs in the gap.

As explained above, according to the first embodiment, in the plasma generating apparatus in which the electrode (the first electrode) to which electric power is applied is detachably attached to the vacuum chamber, the structure is adopted in which, even if the gas pressure of the reactant gas used for generation of plasma is set to gas pressure equal to or higher than 100 pascals and equal to or lower than the atmospheric pressure, an unnecessary discharge is prevented between the electrode (the first electrode) to which electric power is applied and the retaining plate (the conductive retaining member), which is a part of the vacuum chamber, and generation of plasma is performed only in the inter-electrode gap between the electrode (the first electrode) to which electric power is applied and the ground electrode (the second electrode). Therefore, it is possible to realize improvement of plasma generation efficiency.

The thickness of the conductive film for unnecessary discharge prevention is set within the appropriate range (0.1 micrometer to 100 micrometers). Therefore, it is possible to stably maintain, for a long period, the effect that the unnecessary discharge can be suppressed.

### Second Embodiment

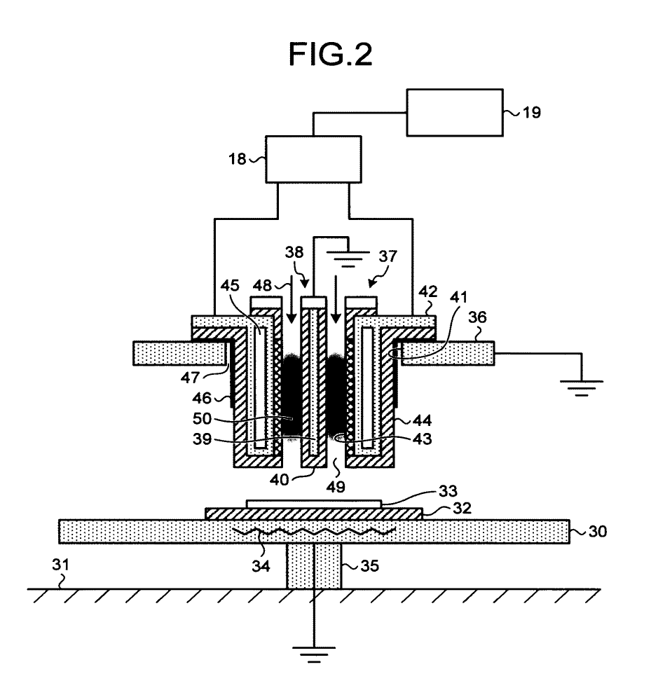

FIG. 2 is a sectional schematic view of the configuration of a plasma generating apparatus according to a second embodiment of the present invention. The matching box 18 and the power supply 19 shown in FIG. 2 are the same as those shown in FIG. 1. In FIG. 2, the entirety of the reaction vessel shown in FIG. 1 serving as the vacuum chamber is not shown. However, the components other than the matching box 18 and the power supply 19 are stored in the reaction vessel.

In FIG. 2, an electrically-grounded flat substrate stage 30 is arranged on a bottom 31 of the reaction vessel. A substrate 33 set as a treatment object is arranged on the upper surface of the substrate stage 30 via a solid dielectric 32. The substrate stage 30 incorporates a heater 34 and can heat the substrate 33 via the solid dielectric 32. In FIG. 2, the flat substrate stage 30 is supported, in parallel to the bottom surface of the reaction vessel, at an end of a column 35 fixed to the bottom 31 of the reaction vessel.

A flat retaining plate 36 is arranged above the substrate stage 30 while being supported by a sidewall of the reaction vessel. The retaining plate 36 is made of a conductive member and electrically grounded. A first electrode set 37 having a cylindrical shape of predetermined length and a second electrode set 38 having a round bar shape arranged at the same length in the center of the cylinder are integrally fixed to this retaining plate 36.

The configuration of the plasma generating apparatus is specifically explained. The second electrode set 38 includes an electrically-grounded ground electrode 39 having a round bar shape and a solid dielectric 40 that covers the outer circumference of the ground electrode 39. Although not shown in the figure, the second electrode set 38 and the first electrode set 37 are coupled via an insulator and integrated. The ground electrode 39 configures the second electrode in claim 2.

The external appearance of the first electrode set 37 has a shape formed by an inserting section having a columnar shape of predetermined length and a flange section provided to project in the radial direction of the inserting section on a draw-out side of the inserting section. In the retaining plate 36, a circular hole 41 slightly larger than the outer diameter of the inserting section of the first electrode set 37 is provided. The length of the first electrode set 37 and the second electrode set 38 is set to length with which the first electrode set 37 and the second electrode set 38 are supported by the retaining plate 36 in a state in which an inserting end of the first electrode set 37 is fit in the circular hole 41 of the retaining plate 36 and the flange section provided on the draw-out end side collides with the retaining plate 36 around the circular hole 41, whereby the end face of the inserting section is opposed to the substrate 33 while maintaining an appropriate space.

The first electrode set 37 includes a power-supply electrode 42, an electrode plate 43, and a solid dielectric 44. The power-supply electrode 42 is a cylindrical structure including the inserting section and the flange section explained above. The electrode plate 43 is bonded over a width area of the inner circumferential surface of the power-supply electrode 42 opposed to the ground electrode set 38. The solid dielectric 44 is bonded to the most part of the outer circumferential surface of the power-supply electrode 42 excluding the arrangement area of the electrode plate 43. A channel 45 is provided on the inside of the power-supply electrode 42. The electrode plate 43 can be cooled by letting a coolant such as water to flow through the channel 45. The power-supply electrode 42 and the electrode plate 43 configure the first electrode in claim 2.

In the first electrode set 37, the flange section provided on the draw-out end side is fixed to the retaining plate 36 by not-shown screws. Consequently, the first electrode set 37 and the second electrode set 38 are integrally fixed to the retaining plate 36. In the first electrode set 37, flange sections are provided in both of the power-supply electrode 42 and the solid dielectric 44. As explained with reference to FIG. 1, to reduce possibility of damage to the solid dielectric 44, it is desirable to provide the flange section in the power-supply electrode 42 as well.

In the first electrode set 37, a conductive film 46 is formed by the method explained in the first embodiment (FIG. 1) on a surface in a predetermined range of the solid dielectric 44 near the retaining plate 36 supported by the retaining plate 36. When the first electrode set 37 is fit in the circular hole 41 of the retaining plate 38 and the flange section is supported by the retaining plate 36, the conductive film 46 formed on the flange section is compression-bonded to the retaining plate 36 and electrically connected to the ground through the retaining plate 36. The inner circumferential diameter of the circular hole 41 of the retaining plate 36 is formed with a margin enough for forming a gap 47 between the circular hole 41 and the conductive film 46 formed on the inserting section. Therefore, it is possible to fix the first electrode set 37 and the second electrode set 38 to the retaining plate 36 without causing the conductive film 46 and the circular hole 41 of the retaining plate 36 to interfere with each other. As explained in the first embodiment (FIG. 1), the thickness of the conductive film 46 is set within the range of 0.1 micrometer to 100 micrometers.

The power supply 19 is connected to the power-supply electrode 42 of the first electrode set 37 via the matching box (the impedance matching box) 18. As explained in the first embodiment (FIG. 1), the power supply 19 is, for example, a high-frequency power supply of 13.56 megahertz, a high-frequency power supply of about several hundred megahertz higher than 13.56 megahertz, or a pulse power supply of several kilohertz.

The plasma generating apparatus according to the second embodiment includes, besides a mechanism for adjusting gas pressure in a vacuum chamber to a fixed value within a range equal to or higher than 100 pascals and equal to or lower than the atmospheric pressure, a mechanism for letting a reactant gas to flow in, from the upper end, to an inter-electrode gap 49 between the first electrode set 37 and the second electrode set 38 and forming a gas flow flowing to the lower end on the substrate 33 side as indicated by an arrow 48.

In the configuration explained above, when predetermined high-frequency power or pulse power is applied to the power-supply electrode 42 in a state in which the gas flow in the direction indicated by the arrow 48 is generated in the inter-electrode gap 49, plasma 50 is generated in the inter-electrode gap 49 by an electric discharge started between the electrode plate 43 and the ground electrode 39. Activated species generated by an electric discharge in this plasma 50 are irradiated on the substrate 33 taking advantage of the gas flow. Predetermined plasma treatment is applied to the substrate 33.

For example, when a silicon plate is used as the electrode plate 43 and a mixed gas of a hydrogen gas and a helium gas is used as the reactant gas let to flow in the direction indicated by the arrow 48, silicon of the silicon plate used as the electrode plate 43 is decomposed by hydrogen radicals generated by the plasma 50. A decomposition product of silicon reaches the substrate 33 heated by the heater 34 and a silicon film is formed on the substrate 33. In the example explained above, a functional thin film is formed on the substrate 33. However, surface modification treatment for the substrate 33 can be performed by the same method.

In this case, a plasma discharge did not occur in the gap 47 between the retaining plate 36 and the conductive film 46 even when the plasma 50 was generated in the inter-electrode gap 49. An effect that an unnecessary discharge was able to be suppressed was confirmed. Like the solid dielectric 14 shown in FIG. 1, a large electric field is applied to the solid dielectric 44 interposed between the conductive film 46 and the power-supply electrode 42. Therefore, similarly, as the solid dielectric 44, it is necessary to select a solid dielectric having thickness and made of a material that can withstand field intensity. For example, when alumina is used as the solid dielectric 44, the thickness of the solid dielectric 44 is desirably equal to or larger than 3 millimeters from the viewpoint of withstand voltage properties and mechanical strength.

In the plasma generating apparatus according to the second embodiment, as explained above, the substrate 33 is arranged on the outside of the inter-electrode gap 49 in which plasma is generated and the plasma generated in the inter-electrode gap 49 can be irradiated on the substrate 33 by the gas flow. Therefore, if relative positions of a plasma generating unit including the first and second electrode sets 37 and 38, which form the inter-electrode gap 49, and the substrate 33 are changed, a plasma irradiation position on the substrate 33 can be changed.

For example, a configuration that can scan a plasma irradiation area on the substrate 33 while keeping the substrate 33 fixed can be realized by coupling the retaining plate 36 to an actuator that moves in three directions of an X axis, a Y axis, and a Z axis. With this configuration, even if the substrate 33 is a large-area substrate, it is possible to apply plasma treatment to the entire large-area substrate by moving the plasma generating unit.

If the retaining plate 36 is an insulator, in some case, the insulator is charged by the power-supply electrode 42. Therefore, measures for preventing an electric shock need to be taken in a place connected to the actuator. The measure for preventing an electric shock can be simplified by grounding the retaining plate 36 serving as the insulator. However, when the retaining plate 36 serving as the insulator is grounded, it is necessary to suppress an electric discharge between the retaining plate 36 and the power-supply electrode 42. In this regard, in the second embodiment, because the retaining plate 36 is made of the conductive member and grounded as explained above, even if the retaining plate 36 according to the second embodiment is coupled to the actuator, it is unnecessary to secure insulation. A plasma generating apparatus of a scan type can be configured with a simple structure.

As explained above, according to the second embodiment, in the plasma generating apparatus in which the treatment object (e.g., the substrate) is arranged on the outside of the inter-electrode gap and plasma generated in the inter-electrode gap is irradiated on the treatment object by the gas flow, as in the first embodiment, the structure is adopted in which, even if the gas pressure of the reactant gas used for generation of plasma is set to gas pressure equal to or higher than 100 pascals and equal to or lower than the atmospheric pressure, an unnecessary discharge is prevented between the electrode (the first electrode) to which electric power is applied and the retaining plate (the conductive retaining member), which is a part of the vacuum chamber, and generation of plasma is performed only in the inter-electrode gap between the electrode (the first electrode) to which electric power is applied and the ground electrode (the second electrode). Therefore, it is possible to realize improvement of plasma generation efficiency.

As in the first embodiment, the thickness of the conductive film for unnecessary discharge prevention is set within the appropriate range (0.1 micrometer to 100 micrometers). Therefore, it is possible to stably maintain, for a long period, the effect that the unnecessary discharge can be suppressed.

### INDUSTRIAL APPLICABILITY

As explained above, the plasma generating apparatus according to the present invention is useful as a plasma generating apparatus that can prevent, even if plasma is generated at gas pressure equal to or higher than 100 pascals and equal to or lower than the atmospheric pressure, an electric discharge in a place where the electric discharge is unnecessary and can realize improvement of plasma generation efficiency.

### REFERENCE SIGNS LIST

1 reaction vessel (vacuum chamber)
2 ground electrode stage
3 gas lead-in port
4 gas exhaust port
5, 14, 32, 40, 44 solid dielectrics
6, 33 substrates (treatment objects)
7, 34 heaters
8, 35 columns
9 electrode set
10, 36 retaining plates
11, 41 circular holes
12, 42 the power-supply electrodes
13, 43 electrode plates
15 hollow
16, 46 conductive films
17, 47 gaps
18 matching box (impedance matching box)
19 power supply
20 plasma
30 substrate stage
31 bottom of reaction vessel
37 first electrode set
38 second electrode set
39 ground electrode
45 channel
48 inflow direction of reactant gas
49 inter-electrode gap
50 plasma

1. A plasma generating apparatus that irradiates plasma on a treatment object, the plasma being generated under gas pressure equal to or higher than 100 pascals and equal to or lower than atmospheric pressure in an inter-electrode gap between a first electrode to which a power supply is connected and a second electrode arranged to be opposed to the first electrode and grounded, wherein
the first electrode has a structure in which the first electrode is retained on a grounded conductive retaining member via a solid dielectric provided on a surface not opposed to the second electrode, and a conductive film is continuously provided on a surface in a predetermined range in contact with the conductive retaining member and a surface in a predetermined range not in contact with the conductive retaining member on a surface of the solid dielectric.

2. The plasma generating apparatus according to claim 1, wherein thickness of the conductive film is equal to or larger than 0.1 micrometer and equal to or smaller than 100 micrometer.

3. The plasma generating apparatus according to claim 1, wherein, in the first electrode, at least the solid dielectric provided on the surface not opposed to the second electrode is detachably supported by the conductive retaining member.

4. The plasma generating apparatus according to claim 1, wherein the treatment object is arranged in the inter-electrode gap.

5. The plasma generating apparatus according to claim 1, wherein the treatment object is arranged on an outside of the inter-electrode gap and the plasma is irradiated on the treatment object by a gas flow generated in the inter-electrode gap.

6. The plasma generating apparatus according to claim 5, wherein
the first electrode and the second electrode are integrated with each other via an insulator that maintains the inter-electrode gap, and
the conductive retaining member can move relatively to the treatment object.
